(19) United States
(12) Patent Application Publication
(10) Pub. No.: US 2007/0001199 A1
(43) Pub. Date: Jan. 4, 2007

(54) Circuits and Integrated Circuits Including Field Effect Transistors Having Differing Body Effects

(75) Inventors: Mike Yen-Chao Shen, Austin, TX (US); William R. Richards JR., Cary, NC (US)

Correspondence Address: MYERS BIGEL SIBLEY & SAJOVEC, PO BOX 37428, RALEIGH, NC, 27627, US

(73) Assignee: Thunderbird Technologies, Inc.

(21) Appl. No.: 11/426,494

(22) Filed: Jun. 26, 2006

Related U.S. Application Data
(60) Provisional application No. 60/695,558, filed on Jun. 30, 2005.

(51) Int. Cl. H01L 29/76

(52) U.S. Cl. 257/288; 257/368; 257/E27.06

(57) ABSTRACT

Field effect transistor integrated circuits include field effect transistors in an integrated circuit substrate, such as a semiconductor substrate. A first one of the field effect transistors has a body effect that is substantially lower than that of a second one of the field effect transistors during operation of the first and second field effect transistors. The field effect transistors may be interconnected to form a circuit, and the body effect of the first field effect transistor is substantially lower than that of the second field effect transistor during operation of the circuit.

### CROSS-REFERENCE TO RELATED APPLICATION

This application claims the benefit of provisional Application No. 60/695,558, filed Jun. 30, 2005, entitled Body Effect Engineering for Planar CMOS Devices, assigned to the assignee of the present invention, the disclosure of which is hereby incorporated herein by reference in its entirety as if set forth fully herein.

### FIELD OF THE INVENTION

This invention relates to electronic circuits and integrated circuit devices, and more particularly to electronic circuits and integrated circuit devices that include insulated gate field effect transistors, often referred to as Metal Oxide Semiconductor Field Effect Transistors (MOSFETs), MOS devices and/or Complementary MOS (CMOS) devices.

### BACKGROUND OF THE INVENTION

Field effect transistors are widely used in integrated circuit devices, including logic, memory, processor and other integrated circuit devices. As the integration density of integrated circuit devices continues to increase, the channel length of a field effect transistor may continue to decrease. These short channel devices may make it increasingly difficult to design high performance circuits and integrated circuits.

### SUMMARY OF THE INVENTION

Field effect transistor integrated circuits according to some embodiments of the present invention include a plurality of field effect transistors in an integrated circuit substrate, such as a semiconductor substrate. A first one of the field effect transistors has a body effect that is substantially lower than that of a second one of the field effect transistors during operation of the first and second field effect transistors. In some embodiments, the plurality of field effect transistors in the integrated circuit substrate are interconnected to form a circuit, and the body effect of the first field effect transistor in the circuit is substantially lower than that of the second field effect transistor in the circuit during operation of the circuit.

In some embodiments, the first field effect transistor is a pass transistor in the circuit. In other embodiments, the circuit may be a ring oscillator or a logic gate, and the first field effect transistor is a pass transistor in the ring oscillator or the logic gate.

In other embodiments, the first field effect transistor has a body or well that floats (i.e., is a floating well or floating body field effect transistor) during operation thereof, and the second field effect transistor has a body or well that is tied to a power supply voltage (a DC voltage or ground) during operation thereof. In still other embodiments, all floating body or floating well field effect transistors in the circuit or in the integrated circuit have a body effect that is substantially lower than all power-supply-voltage-tied body or well field effect transistors in the circuit or in the integrated circuit.

Embodiments of the present invention may be used in conventional MOSFET circuits. In conventional MOSFET circuits, the first field effect transistor may have a body effect that is at least about ten times lower than that of the second field effect transistor during operation thereof Moreover, embodiments of the present invention may be used with Fermi-FET transistors. In these embodiments, the first field effect transistor may have a body effect that is at least about four times lower than that of the second field effect transistor during operation thereof.

In some embodiments, the gate workfunction, tub doping, channel doping, well doping and/or halo doping of the first field effect transistor may be designed to be different from that of the second field effect transistor, so as to provide the body effect of the first field effect transistor that is substantially lower than the body effect of the second field effect transistor. In other embodiments, both the first and second field effect transistors may have a mid-bandgap gate work function, and the tub doping, channel doping, well doping and/or halo doping of the first field effect transistor may be selected to be different from that of the second field effect transistor, so as to provide the body effect of the first field effect transistor that is substantially lower than the body effect of the second field effect transistor.

### BRIEF DESCRIPTION OF THE DRAWINGS

FIG. 1 is a schematic view of a conventional n-channel MOSFET transistor.

FIGS. 2-5 graphically illustrate various behaviors of NMOS transistors.

FIGS. 6-8 are circuit diagrams of an inverter, 2-input NAND gate and 3-input NAND gate.

FIG. 9 graphically illustrates a simulation of an n-channel MOSFET.

FIG. 10 graphically illustrates a doping profile at the center of the channel of the MOSFET of FIG. 9.

FIGS. 11-13 graphically compares measured parameters of MOSFET devices.

FIG. 14 simulates a structure of a Fermi-FET.

FIG. 15 graphically illustrates a doping profile at the center of the channel of the Fermi-FET of FIG. 14.

FIGS. 16 and 17 graphically illustrate various characteristics of n-channel Fermi-FETs.

FIG. 18 illustrates a simulation of a low body effect FET according to some embodiments of the invention.

FIG. 19 illustrates a doping profile of a low body effect FET of FIG. 18 according to some embodiments of the invention.

FIGS. 20-21 graphically illustrate various parameters of a low body effect transistor of FIG. 18 according to some embodiments of the present invention.

FIGS. 22 and 23 are circuit diagrams of ring oscillators.

FIG. 24 graphically illustrates characteristics of a ring oscillator of FIG. 22.

FIGS. 25 and 26 graphically illustrate characteristics of ring oscillators of FIG. 23 according to some embodiments of the present invention.

### DETAILED DESCRIPTION

CMOS devices in conventional bulk technologies are usually designed for specific performance attributes, relative to established reliability criteria. For a conventional surface-channel inversion (SCI) MOSFET, the ability to engineer other attributes of the device may be severely limited. This potential difficulty may arise because the gate workfunction is usually fixed to nearly the band edge of the bulk Si, and the channel doping involves punch-through prevention, well and V_{T} adjust implants, all of the same polarity. Considering the MOSFET's body effect, represented by γ, which expresses dV_{T}/dV_{BS}, circuit designers may need to perform circuit design with whatever body effect parameters result from the available device designs.

It may be advantageous to the circuit designer to provide devices designed specifically for a desired body effect, alongside the conventional designs. There are arguments for providing both high and low body-effect device designs, based upon desired product specifications. As might be expected, there are engineering tradeoffs involved with optimizing any MOSFET for specific attributes. For example, I_{DSAT} might be reduced in order to significantly lower body effect, or short-channel effect (SCE) control might suffer in order to reduce body effect. The ultimate issue, however, may be how the introduction of body effect engineered devices impacts overall circuit performance.

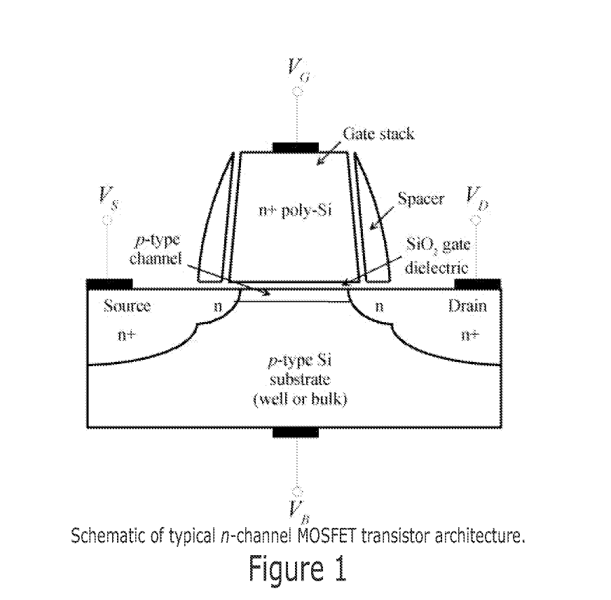

Assuming that it is possible to engineer MOSFETs with γ values both higher and lower than conventional MOSFETs, consider how the altered devices might impact some specific circuit-related issues. As is well-known in the industry, biasing a MOSFET with a non-zero V_{BS} value alters the threshold voltage, V_{T}, of the device, affecting the gₘ and maximum current I_{DSAT} available for conduction. Consider an n-channel MOSFET as shown in FIG. 1. With a positive V_{BS}(V_{B}−V_{S}) applied, making the bulk or well terminal positive with respect to the source, the well-to-source junction becomes forward biased, reducing the V_{T}, thus increasing both the gₘ and I_{DSAT} of the device. Practically, the largest forward bias that can be applied as V_{BS} is about 0.5 V since the junction becomes forward biased. Applying a negative V_{BS} bias, thus reverse biasing the source-bulk junction increases the V_{T}. This can be expressed as follows:

$${V}_{T} = {V}_{FB} + 2 {ϕ}_{F} + \frac{\sqrt{2 {ɛ}_{s} {qN}_{A} ( 2 {ϕ}_{F} - {V}_{BS} )}}{{C}_{OX}} \qquad ( 1 )$$

where V_{FB} is the flatband voltage, largely a function of the gate workfunction Φ_{MS} and interface charges, Φ_{F} is the bulk Fermi level, C_{OX} is the oxide capacitance, N_{A} is the effective bulk doping and q and ε_{S} are physical constants. The expression may be rewritten in terms of the zero-V_{BS} threshold voltage as follows:

$${V}_{T} = {V}_{T} ( {V}_{BS} = 0 ) + γ ( \sqrt{2 {ϕ}_{F} - {V}_{BS}} - \sqrt{2 {ϕ}_{F}} ) \\ where \\ γ = \frac{\sqrt{2 q {ε}_{S} {N}_{A}}}{{C}_{OX}} \qquad ( 2 )$$

which provides a physical basis for the V_{T} shift in terms of fundamental device parameters.

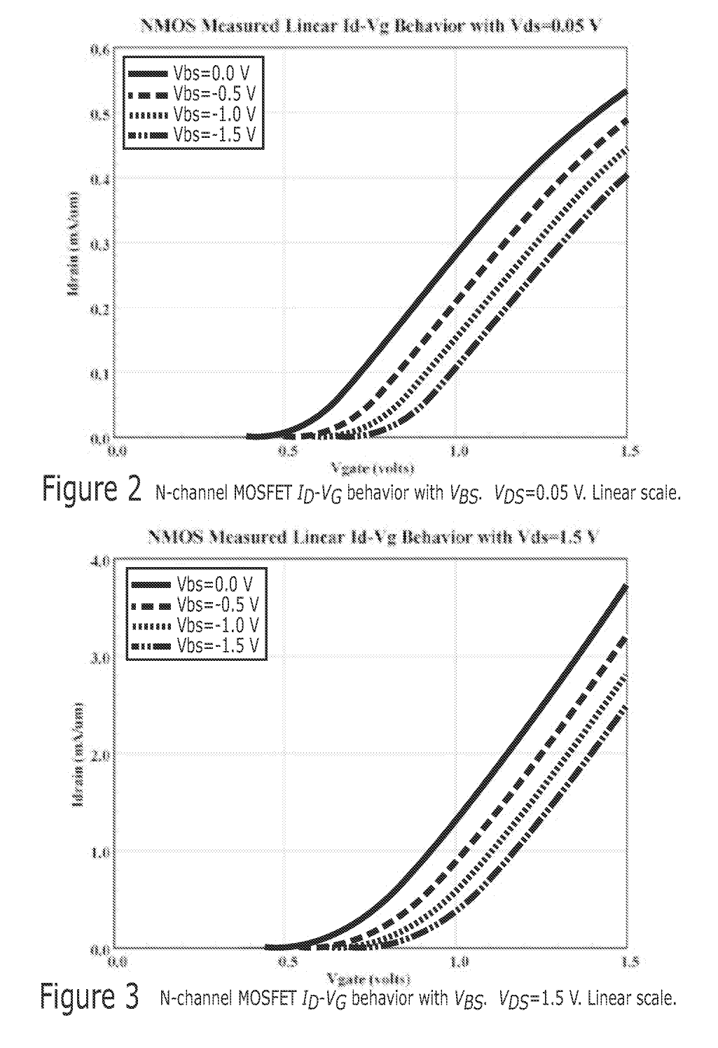

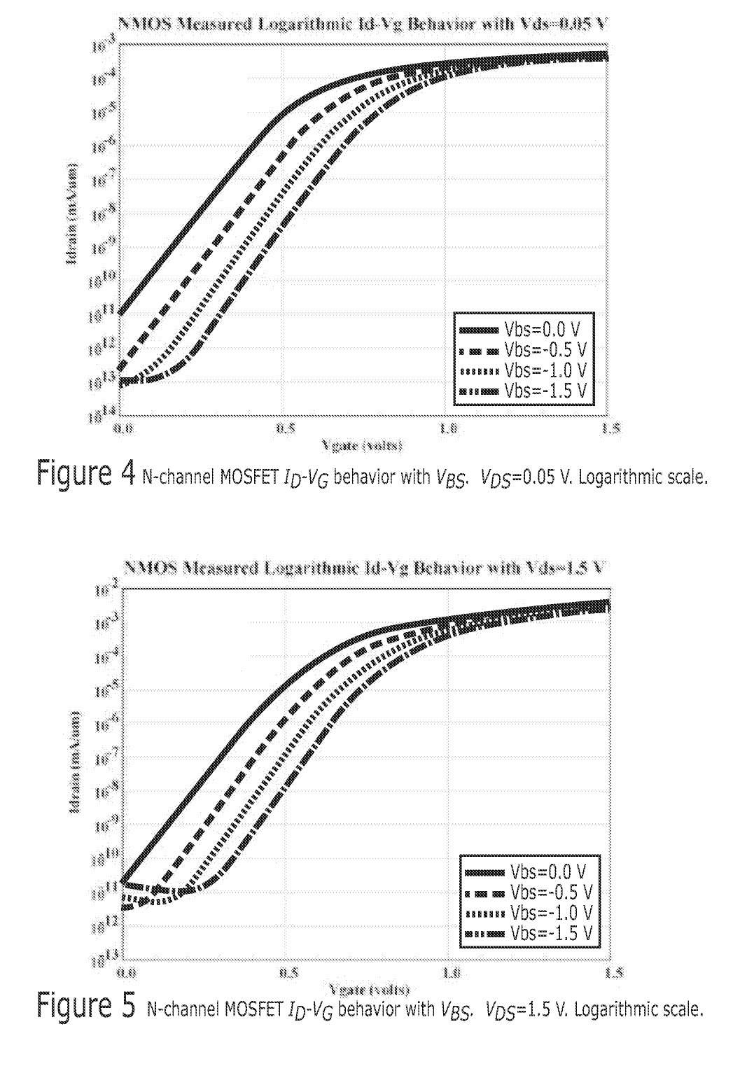

Several points can be made regarding the expression for γ above. First is that this expression is valid for very long-channel, or 1-D device structures. The expressions have been derived based upon a 1-D solution to Poisson's equation for an ideal MOSCAP structure. It has been shown in the literature that for short-channel devices, the influence of the drain potential leads to a reduction in V_{T} as L_{eff} is reduced. If V_{BS} is negative and large, this can offset the short-channel-induced drop in V_{T}, making the V_{T} appear less sensitive to V_{BS}. Note that the opposite effect occurs for a positive V_{BS}. The V_{T} will appear to be more sensitive to V_{BS} since the two effects will be additive. Examining the expression for γ reveals that as tₒₓ is thinned, C_{OX} increases, thus reducing the body effect. For deeply scaled device architectures, however, N_{A} should also increase for conventional SCI devices, offsetting the effect of the reduced tₒₓ. Thus there are several competing effects that should be considered in establishing γ. In general, it has been noted in the literature that the V_{T} of short channel MOSFETs is less sensitive to V_{BS} than long channel devices. To include short-channel effects, the popular BSIM3 Spice model, described in Cheng et al., “BSIM3v3 Mannual”, The Regents of the University of California, Berkeley, Calif., 1996, does not modify the long-channel expression for γ itself, but adds extra terms to the V_{T} expression which are L_{eff} dependent through γ-like parameters. These terms are roughly proportional to V_{BS}. The BSIM3 expressions capture both the short and long channel behavior of V_{T}(V_{BS}) behavior reasonably well. FIGS. 2-5 show a typical effect of V_{BS} on MOSFET I-V behavior based on measured data from a conventional 180 nm CMOS process.

Circuit-Level Motivations for Engineering Body Effect

As CMOS technologies have continued to scale aggressively according to the ITRS roadmap, control of the off-current has become a serious issue. The MOSFET V_{T} values generally decrease as V_{DD} decreases with each technology generation, in order to maintain adequate signal headroom and noise margin. Typically the V_{DD} to V_{T} ratio is larger than three or four for digital circuits to function acceptably. At a V_{DD} of 1.2 V, the device V_{T} values may be on the order of 0.3-0.4 V.

Assuming a typical subthreshold slope of 80 mV/decade, it can be seen that I_{OFF} should be on the order of 4-5 decades below the current at V_{T}. For further reductions in V_{DD}, the I_{ON} to I_{OFF} current ratio can be as small as 3 decades, resulting in leakage currents of about 1-10 nA/μm in magnitude. The resulting chip-level I_{OFF} current for a ULSI design involving more than 10⁸ devices can be amperes in magnitude. It would be highly desirable to be able to dynamically control the V_{T} of individual devices, or at least blocks of devices during chip operation to reduce or minimize the standby current and/or optimize performance. This can be done one of two ways by using the body effect of the MOSFET. In the first method, the devices may be designed with larger V_{T} values at V_{BS}=0 V, or may be designed right at the nominal specifications. A small forward bias is applied to a block of devices as needed to reduce the V_{T} and provide potentially enhanced performance operation. See, for example, Liu et al., “Performance of submicron CMOS devices and gates with substrate biasing”, IEEE International Symposium on Circuits and Systems, Vol. 4, 2000, pp. IV-9 -IV-12. This technique may also alleviate some of the short-channel effects such as V_{T} roll-off with decreasing L_{eff}. This can be referred to as the forward body bias (FBB) technique In the second method, the MOSFETs are designed for full performance at V_{BS}=0 V, and a negative bias is generated on-chip to provide dynamic reverse biasing of blocks of devices in order to turn them off more fully, reducing I_{OFF} considerably. See, for example, Keshavarzi et al., “Effectiveness of Reverse Body Bias for Leakage Control in Scaled Dual Vt MCOS ICs”. Proceedings of the International Symposium on Low Power Electronics and Design, 2001, pp. 207-212. Note that both of these techniques may be more complex in the physical design, may require extra supervisory circuitry, bias generators and/or other considerations. All of these extras may add to the power budget themselves, reducing the potential benefits expected from V_{T} control. Despite the added complexities, the reverse body bias (RBB) technique is used quite often to manage the standby power of very large systems-on-chip. For the RBB technique to work, it may be desirable for the MOSFET's γ to be large enough to provide several orders of magnitude reduction in I_{OFF} at reasonable values of V_{BB}. As noted above, however, deeply scaled technologies appear to be losing the V_{BS} control of V_{T}, which may make the RBB technique much less effective. Another point to note regarding the RBB technique is that it may only be applied to the devices which exist in a well that is junction-isolated from the substrate. For example, if the substrate is effectively n-type, the p-wells may be reverse biased to effectively control V_{T}. If the well is not junction-isolated from the substrate, it may not be free to be biased.

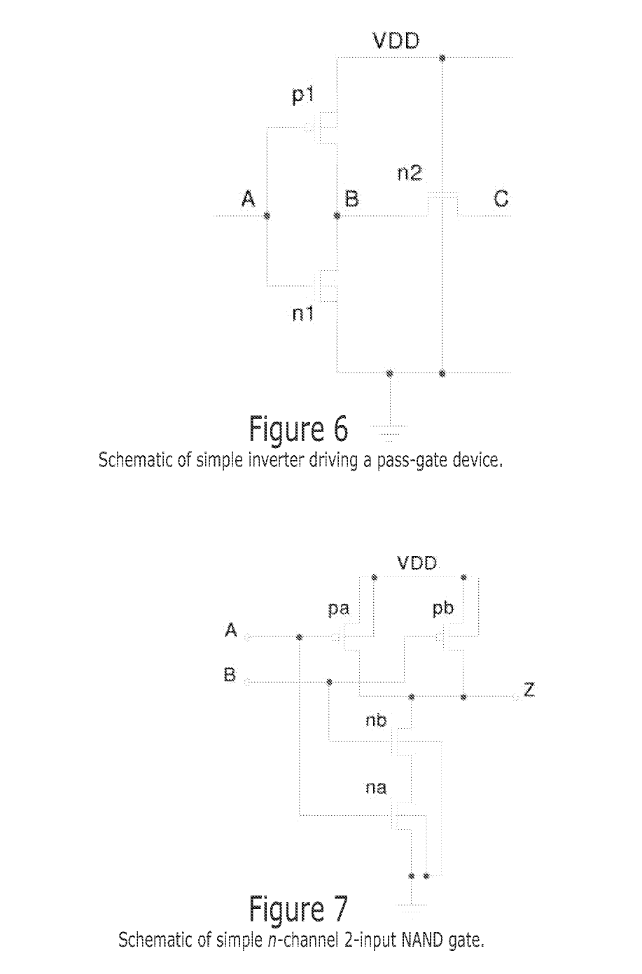

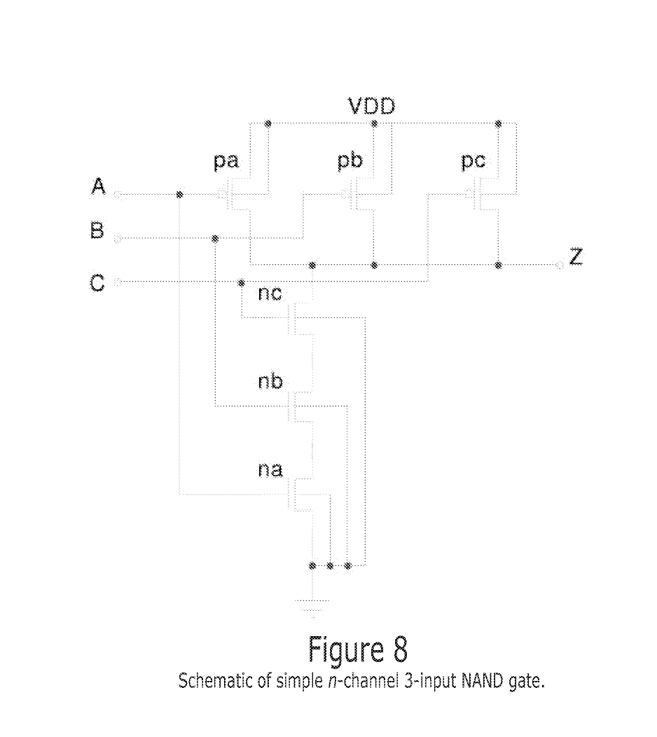

The RBB technique has been used to reduce standby power in large systems and can benefit from a large γ. There are some specific circuit topologies which could benefit from a low γ for performance reasons. One example is the simple pass transistor, commonly used as a signal gating element. FIG. 6 shows a simple case of an inverter, composed of MOSFETs n1 and p1, driving an n-channel pass-gate n2. Since nodes B and C can swing essentially from ground to V_{DD}, the V_{BS} of MOSFET n2 can also vary from V_{BS}=0 V to V_{BS}=−V_{DD}V. If the γ of n2 is large, the gₘ, thus the R_{ON} of this device can suffer dramatically. The use of pass transistors in this fashion can severely degrade the performance of even a simple ring oscillator, as will be shown below. Another very simple circuit is the simple NAND gate. FIG. 7 shows a simple 2-input NAND gate with the n-channel devices stacked. The n-channel device nb will have a non-zero V_{BS} when the Z output is high. If the A input is held high, and the B input is toggled, the performance of the NAND gate may suffer due to the γ of device nb. To compensate for the degradation in performance, the nb device can be made larger (by increasing the device width) than the na device. Note that this may increase parasitic capacitance however, so the gains in dynamic performance may be limited. Also, the increased device width contributes to increased standby power. As more complex, multiple-input gates are used, the performance degradation may become even more severe. FIG. 8 shows an n-channel 3-input NAND gate, where it can be seen that device nc will experience higher V_{B} values than device nb in FIG. 7, due to the triply-stacked n-channel structure. Addressing the degradation by scaling the widths of devices nb and nc may require nc to be larger than nb, and nb larger in width than na, but as in the 2-input case, parasitic capacitances may become even larger and the cell area may increase further with diminishing returns in performance restoration.

According to exemplary embodiments of the invention, device structures can be engineered specifically for lower γ. By mixing these devices with higher performance zero-V_{BS} devices, significant circuit performance enhancements may be gained. Optimizing device structures in this way has become possible only fairly recently due to advances in both channel and gate engineering as well as advanced processing techniques. Engineering control of the gate stack workfunction as well as precise control of the channel and source/drain doping profiles may be employed in exemplary embodiments of the invention.

Device Design Techniques

Referring to Eq. (2), it can be seen that reducing γ for long-channel devices may require an increase in C_{OX}, and/or a decrease in the effective substrate doping N_{A}. To increase γ, the doping N_{A} generally must increase, along with a reduction in C_{OX}, if possible. Both of these movements appear to be completely counter to current scaling theory, which desires an increase in N_{A} as tₒₓ is reduced. For short-channel devices, the design may become more complex due to the influence of the drain field, as well as the 2-dimensional behavior of the dopants. Halo dopings are commonly used in the source/drain engineering of deeply scaled devices, and the halo dopings can significantly impact the nature of the channel. Three different device designs will be used here to illustrate architectural changes to engineer specific body effect behavior, according to exemplary embodiments of the invention.

As a control, an n-channel MOSFET design is presented based upon a commercial 180 nm process. This 180 nm process is then used as a basis to design a 180 nm n-channel Fermi-FET device, and an n-channel low body effect device. See, for example, U.S. Pat. Nos. 4,990,974; 5,151,759; 5,194,923; 5,222,039; 5,367,186; 5,369,295; 5,371,396; 5,374,836; 5,438,007; 5,440,160; 5,525,822; 5,543,654; 5,698,884; 5,786,620; 5,814,869; 5,885,876; and 6,555,872, all of which are assigned to the assignee of the present invention, the disclosures of all of which are incorporated herein by reference as if set forth full herein.

The Fermi-FET device provides higher performance with lower γ than the conventional MOSFET, while the low body effect MOSFET (LOBOFET) provides extremely low γ at the potential expense of zero-V_{BS} performance.

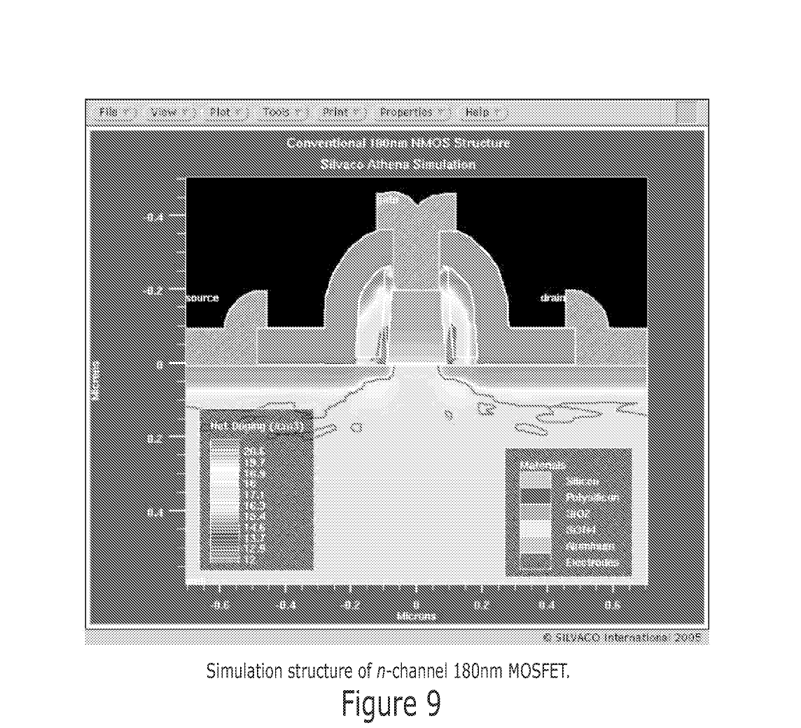

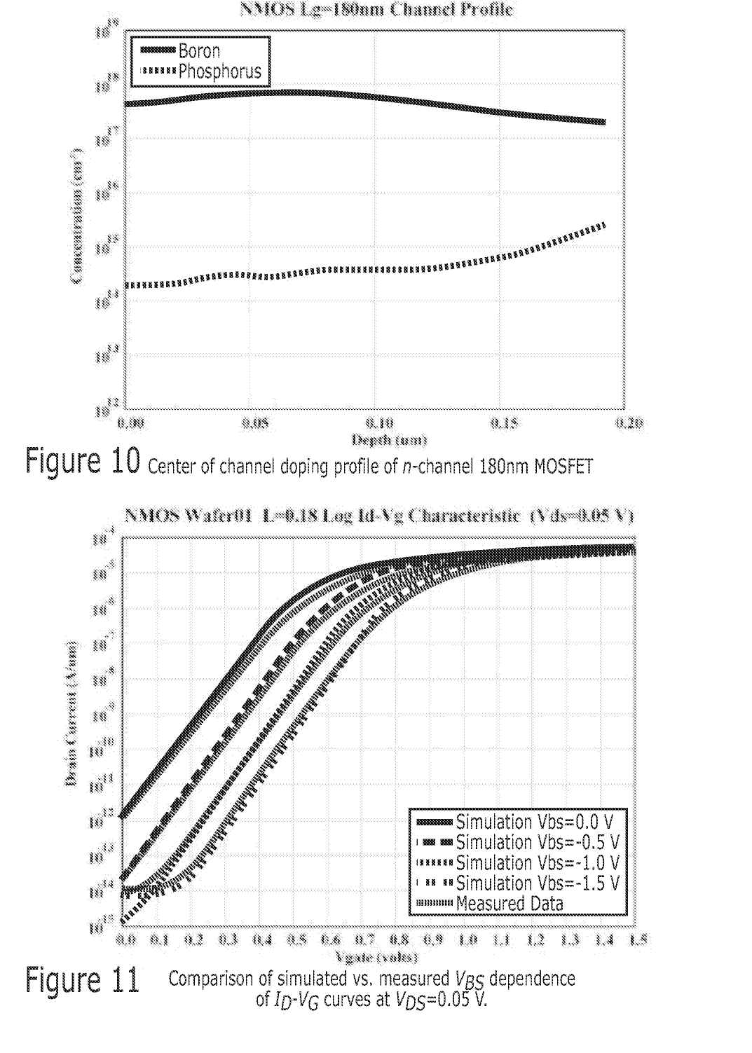

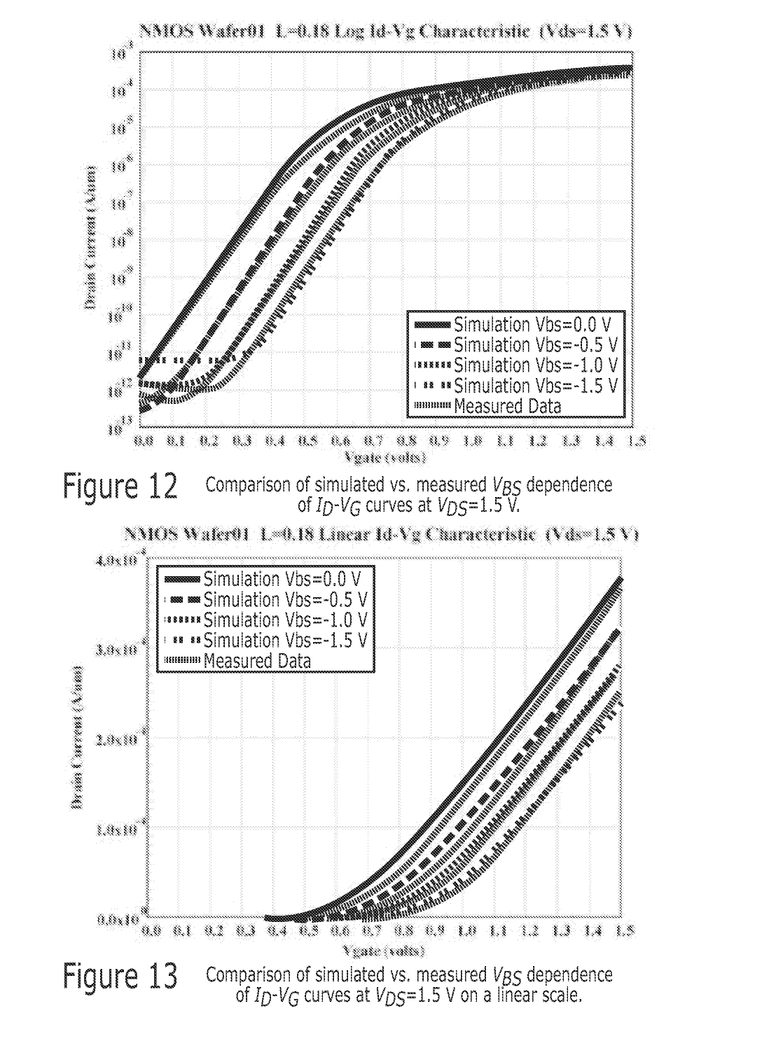

FIG. 9 is a graphic of the conventional MOSFET simulation structure. The 30 presence of the halos is evident below source/drain extension implants at the left and right edges of the gate. BCA Monte Carlo implants were used throughout the simulation for accuracy, leading to the irregular shapes and islands present in the source/drain regions. The lines in these areas delineate the p-n junctions. The gate is conventional n+ polysilicon, with a gate dielectric of silicon dioxide at a thickness of 3.1 nm. Information was available on the doping profiles through foundry-supplied SIMS data, and the profile in the center of the device is shown in FIG. 10. It can be seen that the profile is fairly flat with a surface concentration about 4×10¹⁷ cm⁻³. The device structures were simulated electrically using well-established models which used a minimal amount of adjusting to match the measured characteristics. For this work, special attention was paid to the V_{BS} dependence and the resulting match of the simulations with the measured data is shown in FIGS. 11-12. It can be seen that, though there is some small error in the mobility model just as the device turns on, the overall fit to the subthreshold characteristics is quite good with V_{BS}. The fit is equally as good at both low and drain biases (V_{DS}=0.05 and V_{DS}=1.5 V). This is a good indication that the doping profiles in the process simulation are well-modeled. FIG. 13 shows the same data as in FIG. 12, but on a linear scale, showing more clearly the difference in the mobility model parameters just above V_{T}, but also showing that the V_{BS} is dependence of I_{D} at high V_{G} is also reasonably good. Though not shown here, the NMOS IV and CV behavior for both long and short-channel devices, with V_{BS} dependence agree well with silicon data. The model parameters used for the NMOS calibration were used to design both Fermi-FET and LOBOFET devices.

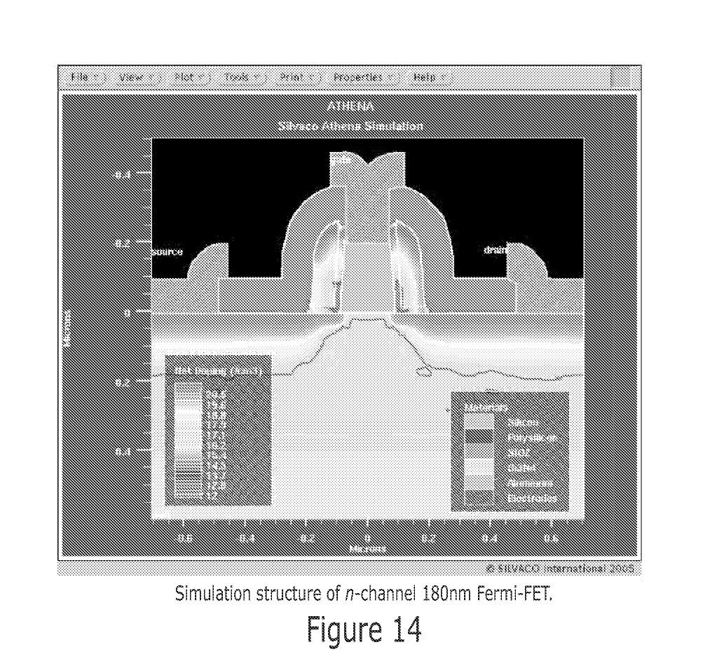

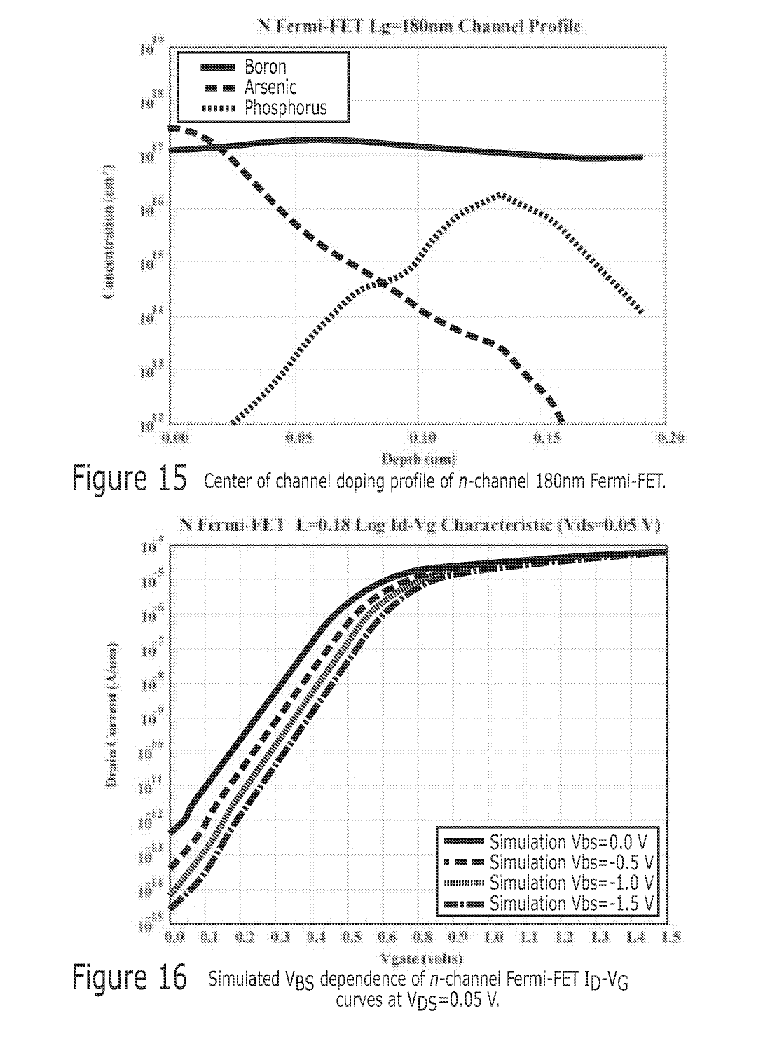

The Fermi-FET device structure is shown in FIG. 14, and the presence of the counter-doped channel is clearly seen. For the Fermi-FET device, the workfunction of the gate material is set to near mid-band, and the gate oxide thickness is 3.1 nm, as in the n-channel MOSFET. The channel impurity profiles are shown in FIG. 15, where the shallow channel junction is evident. The Fermi-FET was designed to be a low-field structure for high performance behavior with a low oxide/interface field at threshold. The characteristics of the Fermi-FET can result from the field tailoring at V_{T}, which generally leads to lower capacitances and higher mobility. No special attempt was made to optimize the structure for low γ or any other characteristics.

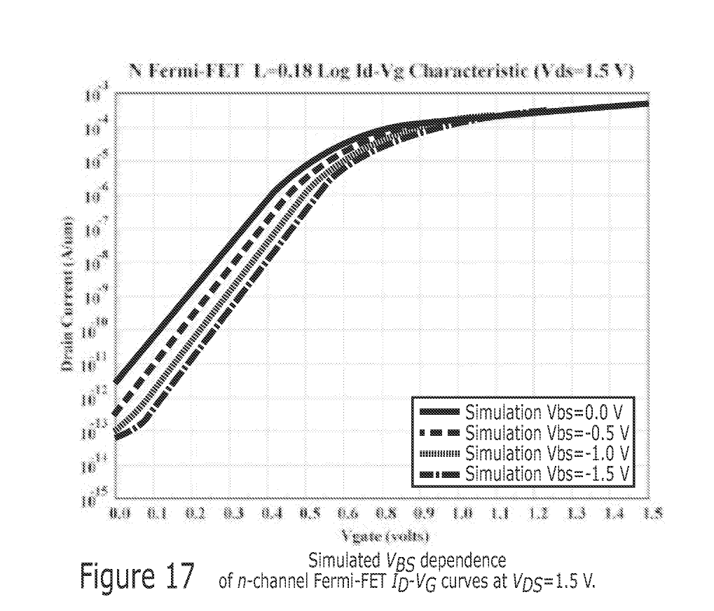

The electrical simulations results are shown in FIGS. 16-17 for both low and high V_{DS}. Comparing these results to FIGS. 11 and 12 reveal a significant reduction in γ for the Fermi-FET design compared with the conventional n-channel MOSFET even with no special optimization. Calculations of γ show the Fermi-FET value to be over 2.5× lower than the NMOS value. This alone is potentially significant, but it was found that the Fermi-FET γ could be lowered even further with further optimization.

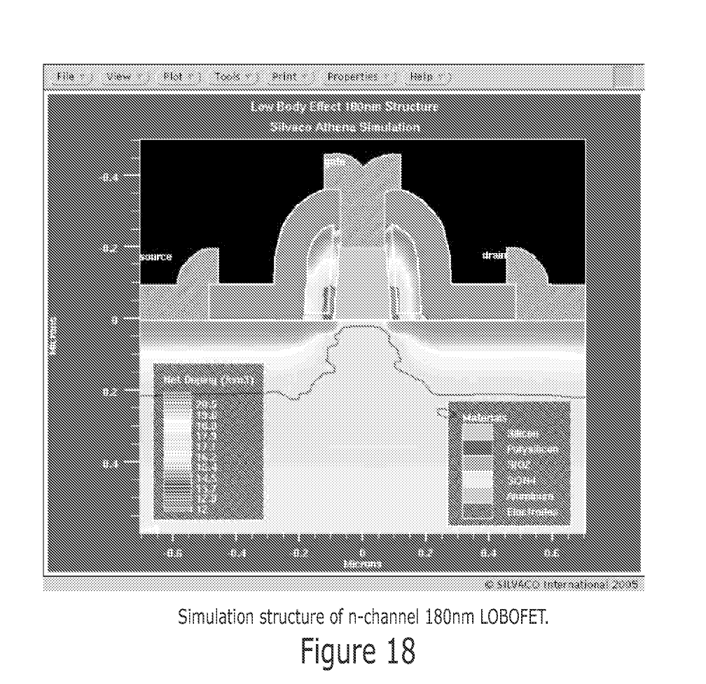

FIG. 18 depicts the structure of the low body effect FET, designated the LOBOFET, which has been specifically engineered for low γ. In order for this to be obtained, it is desirable to be able to tune the gate workfunction in order to set the zero-V_{BS}V_{T} value appropriately for the technology node. Assuming this capability, which is reportedly possible using, for example, Full Silicide (FUSI) gate technology or pure metal with special anneal treatments, the device designer is free to set the channel impurity and halo profiles specifically to lower γ. As seen in FIG. 18, there is still a counter-doped channel present, but this is not a necessary feature for the low body effect FET. Indeed, the surface may be nearly intrinsic, or completely p-type.

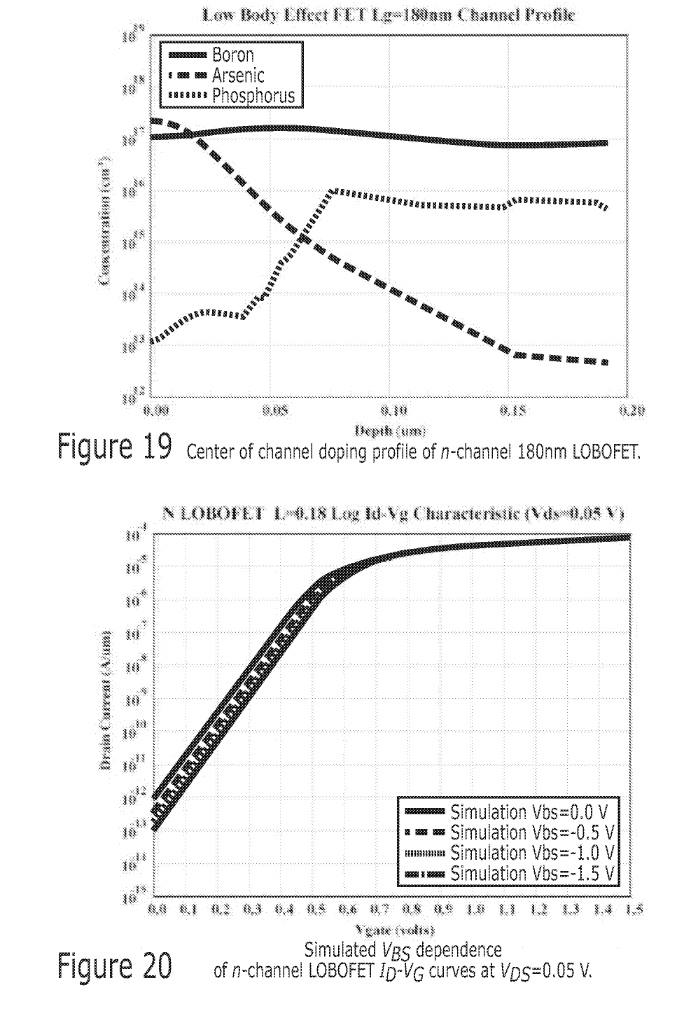

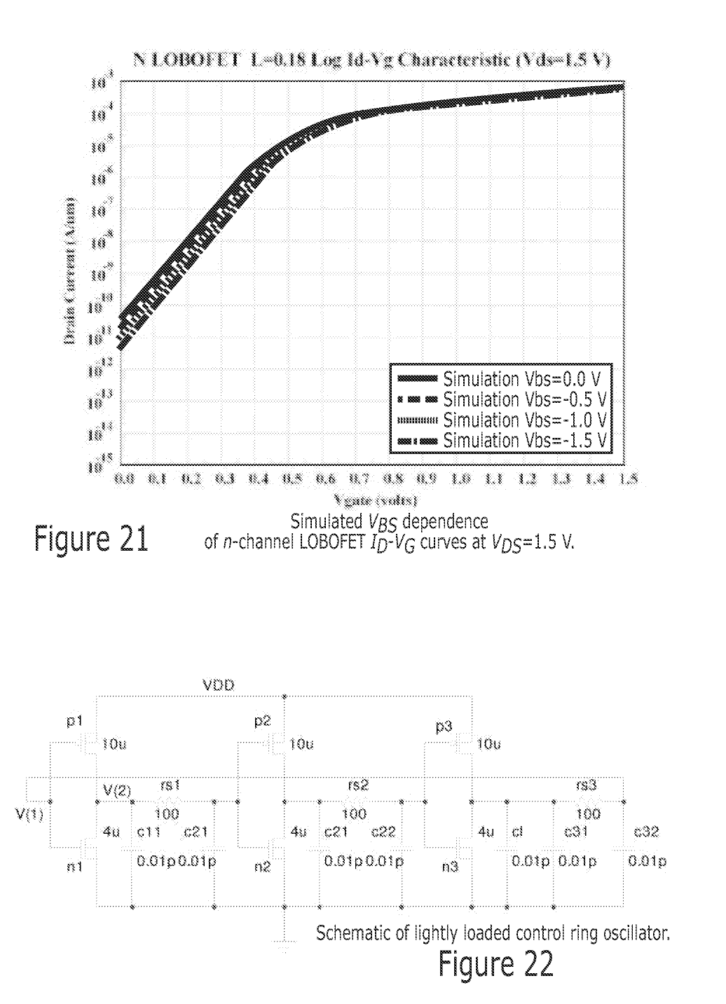

Comparing FIGS. 14 an 18, it can be seen that a LOBOFET can use a significantly reduced halo dose. See, for example, U.S. Pat. No. 6,548,862 to Ryu et al., entitled “Structure of Semiconductor Device and Method for Manufacturing the Same”. The halo is virtually absent. The channel profiles in FIGS. 15 and 19 look rather similar, with the LOBOFET channel implant somewhat lower in dose. Comparing FIGS. 16 with 20, and FIGS. 17 with 21 shows a significant reduction in the spread of the I_{D}-V_{G} characteristics with V_{BS}, indicating a substantially lower γ. Note that the changes to the architecture, compared with the Fermi-FET structure may be rather small, the most prominent appearing to be the halo reduction. The halo reduction may degrade the SCE control of the LOBOFET, but the design objective was to reduce γ with the understanding that other performance criteria may suffer. That was accomplished with the current LOBOFET design.

Table 1 shows the gamma values extracted from MOSFET data and simulations, Fermi-FET simulations and the LOBOFET design. The long-channel γ values are measured data, and show that the simulation values are reasonable. As can be seen in Table 1, the gamma of the low body effect FET device is almost one fourth that of the normal Fermi-FET, 20 and almost a factor of ten lower than the MOSFET. These gamma values can have a significant effect on circuit performance, and were studied using ring oscillators.

TABLE 1
Extracted gamma values for short-channel (L_{G} = 0.18 μm) simulations
and long-channel (L_{G} = 1.0 μm) measurements from foundry.

| | Gamma (simulated) | Gamma (data) |
|---|---|---|
| Device | L_{G} = 0.18 um | L_{G} = 1.0 um |
| n-MOSFET | 0.5364 | 0.44 |
| n-Fermi-FET | 0.2036 | 0.17 |
| n-LB-Fermi-FET | 0.0548 | |

In a typical foundry process, devices with different threshold voltage values may be provided. These devices are typically achieved with different threshold voltage adjust implants before the formation of gate-oxide. A difference of 2-3× channel doping difference can exist between low and high threshold voltage devices, which according to eq. (2), translates to 30-40% decrease to the body effect, gamma. However, this result is only valid in long channel case since the localized halo doping need to be taken into account in the short channel case.

When designing specifically for a low body effect, tradeoffs generally may exist among device properties. In particular, as has been discussed, in some embodiments, it may be desirable to reduce halo dose as the principal parameter to reduce body effect. This may have a significant impact on short-channel effects, and/or the performance of the device at zero body bias. What is generally of interest, however, is the device performance at non-zero V_{BS} values. Thus, it may be desirable to suffer degradation in device behavior at zero V_{BS} in order to provide enhanced performance at non-zero V_{BS}. As an example, consider a Fermi-FET device design which includes a counter-doped tub and adjusted gate workfunction to achieve characteristics of a Fermi-FET. For a long-channel device, either Fermi-FET or MOSFET, in order to adjust gamma, it may be desirable to adjust the well profile. Being long-channel, the halo implants may have little effect on the device properties. In contrast, for a short-channel device, the halo implants can have a significant effect on device behavior. Simulations were performed on a Fermi-FET device design similar to the structure described above. A single parameter, the halo dose, was varied over four values and a few of the device properties examined. The results are summarized in Table 2 below.

TABLE 2
Extracted gamma values for short-channel (L_{G} = 0.18 μm)
Fermi-FET simulations with halo dose varied as parameter.

| Halo Dose | Gamma | DIBL | V_{TH} |
|---|---|---|---|
| 0.5e13 | 0.077 | 0.085 | 0.366 |
| 1.0e13 | 0.120 | 0.065 | 0.415 |
| 1.5e13 | 0.178 | 0.053 | 0.450 |
| 2.0e13 | 0.247 | 0.049 | 0.460 |

It can be seen that the gamma is significantly affected, with the minimum at low halo dose as discussed above. The effect on DIBL is seen in column 3, and the V_{TH} at V_{DS}=1.5 V is shown in column 4. No adjustment in gate workfunction was made to correct for the large variations in V_{TH}. In practice, this may be done to keep leakage under control. As noted before, the halo dose is only one of a number of parameters which may be varied to achieve the desired channel profile for low body effect.

Referring to Eq. (2), the γ is inversely proportional to C_{OX}. Thus, reducing tₒₓ allows the γ to be reduced. For the gate and channel-engineered structures shown here as Fermi-FETs and LOBOFETs, the internal fields are typically smaller compared with a conventional MOSFET, allowing the gate oxide to be thinned. Note also that the extra degrees of freedom provided by the gate workfunction and the counter-doped channel through the channel doping N_{D}, the substrate doping N_{A} and the junction depth Xⱼ can allow the device to be optimized more flexibly. For short-channel Fermi-FET/LOBOFET devices, due to the gate and channel engineering discussed here, more flexibility may also exist in altering the halo and source/drain extension profiles. In general, the design flexibility may arise from the use of a near mid-bandgap workfunction for the gate. In fact, it is possible to design a LOBOFET with no channel junction at all, by optimizing the channel/well profiles, and the halo and source/drain extension profiles.

Ring Oscillator Simulation Study

A study was performed to explore the behavior of body-effect engineered device technology in 3-stage ring oscillators with and without pass transistors. Significant degradation in ring oscillator performance with pass transistors was found, as might be expected. The study was performed using Silvaco International's Atlas MixedMode-XL numerical/Spice simulator which allows simulation of Spice circuit simulation netlists self-consistently with numerical device simulations. Key or critical transistors may be simulated using full 2-D numerical structures without the need for accurate compact analytical models, such as the BSIM3/BSIM4 models. The circuit impact of novel device structures may be explored without the need to develop a compact model.

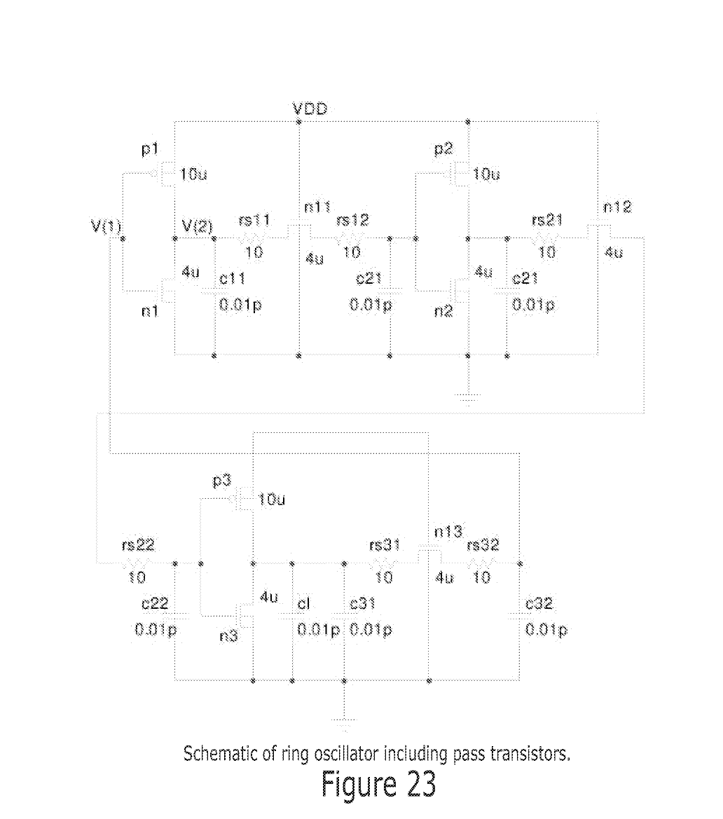

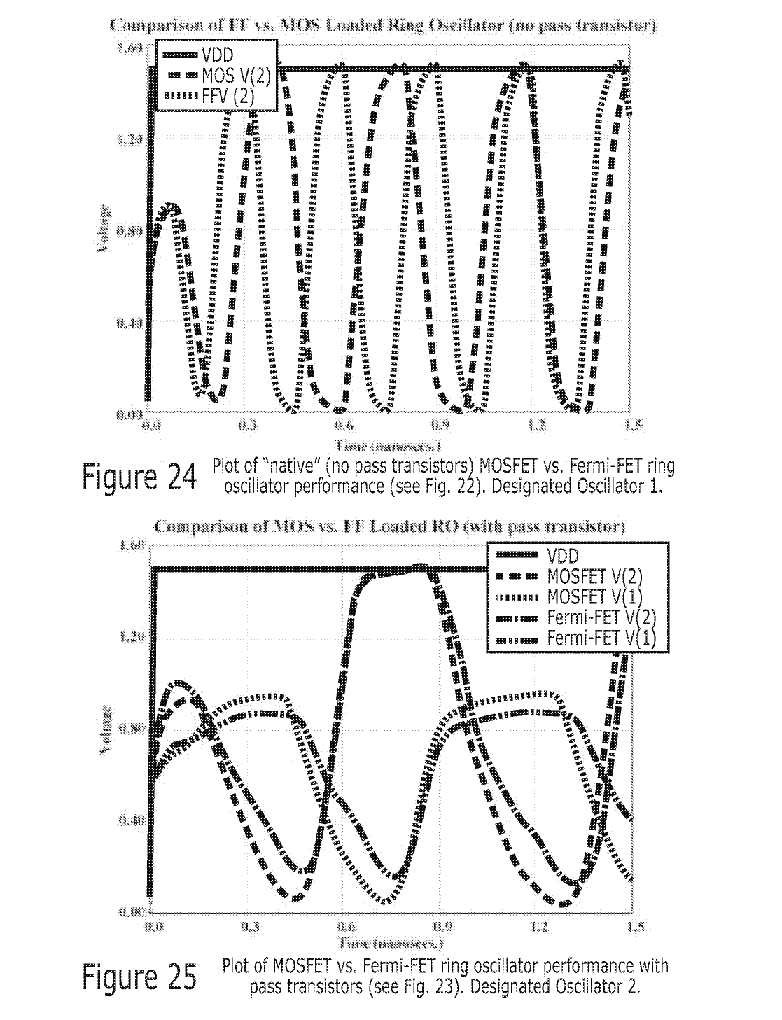

Three circuits were contrasted: MOSFET and Fermi-FET ring oscillators with no pass transistors (FIG. 22), MOSFET and Fermi-FET ring oscillators with pass transistors (FIG. 23), and a Fermi-FET ring oscillator with the pass transistors being the special, low body effect (LOBOFET) design (FIG. 23).

Simulation Results

The ring oscillator schematics which were simulated are shown in FIGS. 22 and 23. FIG. 22 is the native, lightly loaded control oscillator using conventional MOSFETs. The effects of parasitic routing load were included as a simple lumped-element pi network. The schematic in FIG. 23 includes pass transistors which split the pi load network. All of the transistors in both FIGS. 22 and 23 were modeled numerically using the structures shown above; no Spice models were used for the transistors, to assure optimum accuracy. As mentioned above, three cases were simulated; the control with no pass transistors (FIG. 22) designated Oscillator 1, a case comparing MOSFET and Fermi-FET ring oscillators with pass transistors (FIG. 23) designated Oscillator 2, and a third case where transistors n11, n12, and n3 in FIG. 23 are replaced by LOBOFET devices for the Fermi-FET ring oscillator, designated Oscillator 3.

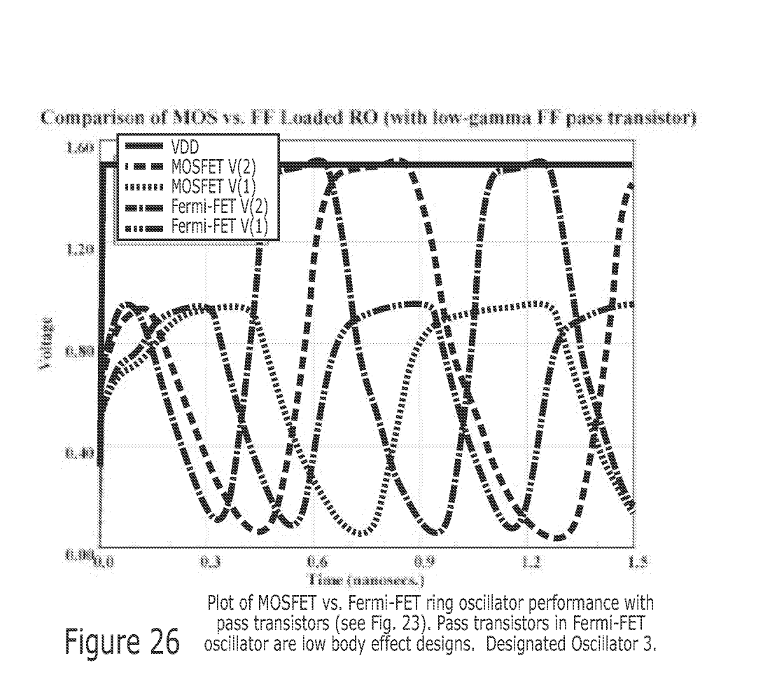

The simulation results are depicted in FIGS. 24-26, and the delay results are tabulated in Table 2. The signals at the input and output of the first stage of each oscillator are shown as V(1) and V(2), respectively in FIGS. 25 and 26. Since Oscillator 1 has no pass transistors, FIG. 24 only shows signal V(2). As seen in Table 3, the “native” Fermi-PET oscillator (with no pass transistor) is 35% faster than the “native” MOSFET (with no pass transistor). This is consistent with prior Fermi-FET experience with both simulated and measured silicon performance. The intrinsic Fermi-FET delay is faster, and in prior work the slope of delay vs. load decreases significantly comparing Fermi-FET with MOSFET performance, meaning not only is the intrinsic delay shorter, but the Fermi-FET drives heavier loads more effectively.

TABLE 3
Tabulation of delay results for native oscillators with
no pass transistor (Oscillator 1), oscillators with pass
transistor (Oscillator 2) and Fermi-FET oscillator with
LB-Fermi-FET pass transistor (Oscillator 3).

| | Oscillator 1 | Oscillator 2 | Oscillator 3 |
|---|---|---|---|
| | Delay (ps) | Delay (ps) | Delay (ps) |
| Fermi-FET | 290.0 | 865.4 | 617.8 |
| MOSFET | 392.3 | 844.2 | 844.2 |
| Ratio | 1.353 | 0.976 | 1.366 |

FIG. 25 appears somewhat surprising. Since the Fermi-FET γ is somewhat lower (4×) than the MOSFET, and the Fermi-FET should have lower R_{ON} than the MOSFET, there should have been some improvement in performance for the Fermi-FET, however small. This was not the case, however and in fact the Fermi-FET oscillator appears slightly slower than the MOSFET. The waveforms at V(1) indicate that the signal swing across the pass transistor is reduced for the Fermi-FET oscillator, but it is not clear why yet. It is possible that the parasitic Fermi-FET capacitance may be responsible for the unexpected delay behavior.

FIG. 26 shows the results with the Fermi-FET pass transistors replaced with the low body effect LOBOFETs. Here it is seen that the performance advantage may be more than restored. The LOBOFET oscillator actually shows a slight performance advantage over the native oscillator performance.

Table 3 tabulates the delay values extracted from the MixedMode simulations. The three columns compare the Fermi-FET and MOSFET oscillator delays for the three cases identified above, It can be seen from oscillator 3 that the use of the LOBOFET provides a Fermi-FET delay improvement of over 36%.

Conclusions

From these simulations, it can be seen that it is possible to tune MOSFET devices for other criteria, such as low body effect, as opposed to the traditional metrics of Ion vs Ioff, threshold voltage, subthreshold slope, etc . . . , with control over the gate workfunction, a counter-doped channel and source/drain engineering. This tuning may be made possible because the workfunction-engineered/channel-engineered design can provide more degrees of freedom than conventional MOSFET architectures. By controlling the characteristics of the channel implants, including the dopant depths, shapes of the profiles, and the doping levels, and/or engineering the gate workfunction, it is possible to achieve a wide range of characteristics. For the case of a desired low body effect, simulations indicate that the body effect of a properly tuned LOBOFET structure can be a factor of ten lower than a conventional MOSFET. This can have a significant effect on circuit performance for the ring oscillator cases studied here. Note that other techniques have been reported in the literature which can provide devices with low body effect by emulating SOI behavior in bulk. See, for example, Inaba et. al., “SODEL FET: Novel Channel and Source/Drain Profile Engineering Schemes by Selective Si Epitaxial Growth Technology”, IEEE Trans. Elect. Devices, Vol. 51, No. 9, 2004, pp. 1401-1408. These techniques appear to be more complex and may require expensive process steps such as selective epitaxial growth.

Further work may be done to understand the tradeoffs among the device γ, R_{ON} and capacitances. This may provide understanding of device design features to optimize the low body effect architecture. Also, from this work it appears that there is a threshold gamma value which may significantly degrade ring oscillator performance. Intuitively this makes sense, since the signal swing across the pass transistor is determining the drive available to the next stage. The signal swing at the input side of the pass transistor also suggests how the switch point of the following stage should be skewed for best performance. Further work may study these effects more thoroughly.

In general, from a circuit design perspective, in some embodiments, it may be desirable to replace every MOSFET having a floating body or well with a LOBOFET, leaving the devices with supply-tied wells as either MOSFETs or Fermi-FETs. The supply-tied well devices could be optimized purely for zero V_{BS} performance. The floating-well or body devices could then be implemented as LOBOFETs, to allow overall performance enhancement. Virtually all combinational logic functions more complex than an inverter may benefit from this approach. Multiple-input NAND gates, NOR gates, AOI gates, etc. may all benefit from low body effect devices in the device stacks. In addition, dynamic circuit elements such as dynamic flip-flops which use pass transistors extensively may also benefit. Note that the approach of modifying channel profile or halo characteristics for low body effect is not limited to n-channel devices. Both the n and p-channel devices may be separately designed for low body effect. This is in contrast to the well biasing techniques conventionally used to control V_{TH}, which generally may be limited to either n or p-channel devices only, depending on how the wells are established in the process flow. Also, since the performance enhancement may be provided at the transistor level, circuit complexity may be significantly reduced by not having to manage well biasing throughout a large chip.

Including these specially tuned low body effect FETs within a conventional MOSFET or Fermi-FET process flow can be fairly trivial, and may require one to two extra mask steps. There is no reason why these devices can not be mixed with conventional MOSFETs and/or Fermi-FETs. Development of the LOBOFET design could take place in parallel with the development of a conventional Fermi-FET process flow with little additional engineering effort required.

Accordingly, some embodiments of the present invention can change the body effect of selected transistors in a given circuit or in a given integrated circuit, to provide transistors having different body effects in a given circuit or on a given chip. This may be contrasted with conventional circuits or chips, which may toggle the substrate bias across a circuit or chip. Low body effect devices may be provided by controlling one or more of the following parameters, as was described above: gate work function, channel tub doping, channel well doping and/or halo doping. Moreover, some embodiments of the present invention can mix Fermi-FET and low body effect transistors in a given circuit. Yet other embodiments can mix low body effect devices and conventional MOSFETs in a given circuit. In some embodiments, low body effect devices may be provided by providing mid-bandgap gate work functions in all devices, and then varying the halo and/or tub/channel design, to produce a desired body effect.

The present invention has been described herein with reference to the accompanying drawings, in which exemplary embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Moreover, each embodiment described and illustrated herein includes its complementary conductivity type embodiment as well. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items and may be abbreviated as “l”.

Embodiments of the invention were described herein with reference to illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A field effect transistor integrated circuit comprising:
a plurality of field effect transistors in an integrated circuit substrate, a first one of the field effect transistors having a body effect that is substantially lower than that of a second one of the field effect transistors during operation of the first and second field effect transistors.

2. A field effect transistor integrated circuit according to claim 1 wherein the first field effect transistor has a body or well that floats during operation thereof and wherein the second field effect transistor has a body or well that is tied to a power supply voltage during operation thereof.

3. A field effect transistor integrated circuit according to claim 1 wherein all field effect transistors in the integrated circuit that have a body or well that floats have a body effect that is substantially lower than all field effect transistors in the integrated circuit that have a body or well that is tied to a power supply voltage.

4. A field effect transistor integrated circuit according to claim 1 wherein the second field effect transistor is a MOSFET and wherein the first field effect transistor has a body effect that is at least about ten times lower than that of the second field effect transistor during operation of the first and second field effect transistors.

5. A field effect transistor integrated circuit according to claim 1 wherein the second field effect transistor is a Fermi-FET and wherein the first field effect transistor has a body effect that is at least about four times lower than that of the second field effect transistor during operation of the first and second field effect transistors.

6. A field effect transistor integrated circuit according to claim 1 wherein a gate work function, tub doping, channel doping, well doping and/or halo doping of the first field effect transistor is different from that of the second field effect transistor so as to provide the body effect for the first field effect transistor that is substantially lower than the body effect of the second field effect transistor.

7. A field effect transistor integrated circuit according to claim 1 wherein both the first and second field effect transistors have a mid-bandgap gate work function and wherein a tub doping, channel doping, well doping and/or halo doping of the first field effect transistor is different from that of the second field effect transistor so as to provide the body effect for the first field effect transistor that is substantially lower than the body effect of the second field effect transistor.

8. A field effect transistor integrated circuit according to claim 1 wherein the plurality of field effect transistors in the integrated circuit substrate are interconnected to form a circuit and wherein the body effect of the first field effect transistor in the circuit is substantially lower than that of the second field effect transistor in the circuit during operation of the circuit.

9. A field effect transistor integrated circuit according to claim 8 wherein the first field effect transistor is a pass transistor in the circuit.

10. A field effect transistor integrated circuit according to claim 8 wherein the circuit is a ring oscillator or a logic gate and wherein the first field effect transistor is a pass transistor in the ring oscillator or the logic gate.

11. A field effect transistor integrated circuit according to claim 8 wherein the first field effect transistor has a body or well that floats during operation thereof and wherein the second field effect transistor has a body or well that is tied to a power supply voltage during operation thereof.

12. A field effect transistor integrated circuit according to claim 8 wherein all field effect transistors in the circuit that have a body or well that floats have a body effect that is substantially lower than all field effect transistors in the circuit that have a body or well that is tied to a power supply voltage.

13. A field effect transistor integrated circuit according to claim 8 wherein the second field effect transistor is a MOSFET and wherein the first field effect transistor has a body effect that is at least about ten times lower than that of the second field effect transistor during operation of the first and second field effect transistors.

14. A field effect transistor integrated circuit according to claim 8 wherein the second field effect transistor is a Fermi-FET and wherein the first field effect transistor has a body effect that is at least about four times lower than that of the second field effect transistor during operation of the first and second field effect transistors.

15. A field effect transistor integrated circuit according to claim 8 wherein a gate work function, tub doping, channel doping, well doping and/or halo doping of the first field effect transistor is different from that of the second field effect transistor so as to provide the body effect for the first field effect transistor that is substantially lower than the body effect of the second field effect transistor.

16. A field effect transistor integrated circuit according to claim 8 wherein both the first and second field effect transistors have a mid-bandgap gate work function and wherein a tub doping, channel doping, well doping and/or halo doping of the first field effect transistor is different from that of the second field effect transistor so as to provide the body effect for the first field effect transistor that is substantially lower than the body effect of the second field effect transistor.
